(19) United States
(12) Patent Application Publication
(10) Pub. No.: US 2025/0316482 A1
(43) Pub. Date: Oct. 9, 2025

(54) GATE ELECTRODE DEPOSITION IN STACKING TRANSISTORS AND STRUCTURES RESULTING THEREFROM

(71) Applicant: Taiwan Semiconductor Manufacturing Co., Ltd., Hsinchu (TW)

(72) Inventors: Kai-Chieh Yang, New Taipei City (TW); Kuan-Kan Hu, Hsinchu (TW); Wei-Yen Woon, Taoyuan (TW); Ku-Feng Yang, Baoshan Township (TW); Szuya Liao, Zhubei (TW)

(21) Appl. No.: 19/240,857

(22) Filed: Jun. 17, 2025

Related U.S. Application Data
(63) Continuation of application No. 18/601,167, filed on Mar. 11, 2024.
(60) Provisional application No. 63/582,929, filed on Sep. 15, 2023.

(51) Int. Cl. H01L 21/28; H10D 30/43; H10D 30/67; H10D 84/03; H10D 87/00; H10D 88/00

(52) U.S. Cl. CPC H01L 21/28088; H10D 30/6739; H10D 84/038; H10D 87/00; H10D 88/01; H10D 30/43; H10D 30/6757

(57) ABSTRACT

A method of forming a semiconductor device includes depositing a target metal layer in an opening. Depositing the target metal layer comprises performing a plurality of deposition cycles. An initial deposition cycle of the plurality of deposition cycles comprises: flowing a first precursor in the opening, flowing a second precursor in the opening after flowing the first precursor, and flowing a reactant in the opening. The first precursor attaches to upper surfaces in the opening, and the second precursor attaches to remaining surfaces in the opening. The first precursor does not react with the second precursor, and the reactant reacts with the second precursor at a greater rate than the reactant reacts with the first precursor.

### PRIORITY CLAIM AND CROSS-REFERENCE

This application is a continuation of U.S. application Ser. No. 18/601,167, filed on Mar. 11, 2024, which claims the benefit of the following provisionally filed U.S. Patent application: Application No. 63/582,929, filed on Sep. 15, 2023, and entitled “Two-Precursor Method for Seam-Free Metal Gap Fill,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stack transistor (e.g., a CFET) in accordance with some embodiments.

FIGS. 2, 3, 4, 5A, 5B, 6, 7, 8, 9, 10, and 11 are views of intermediate stages in the manufacturing of stacking transistors in accordance with some embodiments.

FIGS. 12A, 12B, 12C, 12D, and 12E are flow diagrams of an example process for forming a gate electrode of a stacking transistor in accordance with some embodiments.

FIG. 13 illustrates differences in sticking coefficients of different deposition precursors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure and the method of forming the same are provided. In various embodiments, the stacking transistor includes a gate electrode with one or more work function metal (WFM) layers. The WFM layers may be deposited with a chemical vapor deposition (CVD) and/or atomic layer deposition (ALD) process in which a number of deposition cycles are performed.

An initial deposition cycle includes flowing a first precursor and a second precursor into a gate opening for depositing the WFM layer. The first precursor may be, for example, a metal halide, with a relatively high sticking coefficient while the second precursor may be, for example, a metal carbonyl with a relatively low sticking coefficient. As a result of the different sticking coefficients and by controlling one or more deposition parameters (e.g., flow rate and/or flow time), the first precursor may primarily attach to upper surfaces within the gate opening, and the second precursor attaches to remaining surfaces (e.g., primarily lower surfaces) within the gate opening. After the first and second precursors are flowed into the gate opening, a reactant (sometimes referred to as a third precursor) is then flowed into the gate opening. The reactant may react at a higher rate with the second precursor (e.g., along bottoms of the gate opening) than the first precursor (e.g., along tops of the gate opening). For example, one or more process parameters may be controlled to increase reactions with the second precursor and/or reduce reactions with the first precursor. In this manner, the first precursor may act as a self-inhibition reagent that reduces the formation of the WFM at the top surfaces of the gate opening while the WFM is formed in the bottom of the openings.

The deposition cycles may continue until a desired thickness of WFM is deposited. Each of the subsequent deposition cycles includes flowing at least the second precursor and the reactant. Certain deposition cycles (e.g., every other cycle, every third cycle, or so forth) may also include flowing the first precursor to reduce growth at tops of the gate opening. Thus, the WFM layer may be grown primarily from the bottom of the gate opening to the top of the gate opening in a bottom-up, seam-less deposition process.

Embodiments may achieve one or more advantages. For example, various embodiments provide an approach to achieve seam-free gap filling in complex geometric structures (e.g., within gate openings). The resulting seam-free structures (e.g., gate stack) may provide lower resistance, which improves device performance. Further, in stacking transistors, the WFM of a lower gate stack may be etched back, and the seam-free gate stack provides improved control during etch-back processes. For example, etching a seam-free gate stack may provide an improved etch profile and improved depth uniformity. Thus, embodiments allow for increased processing ease, improved processing control, and improved electrical performance.

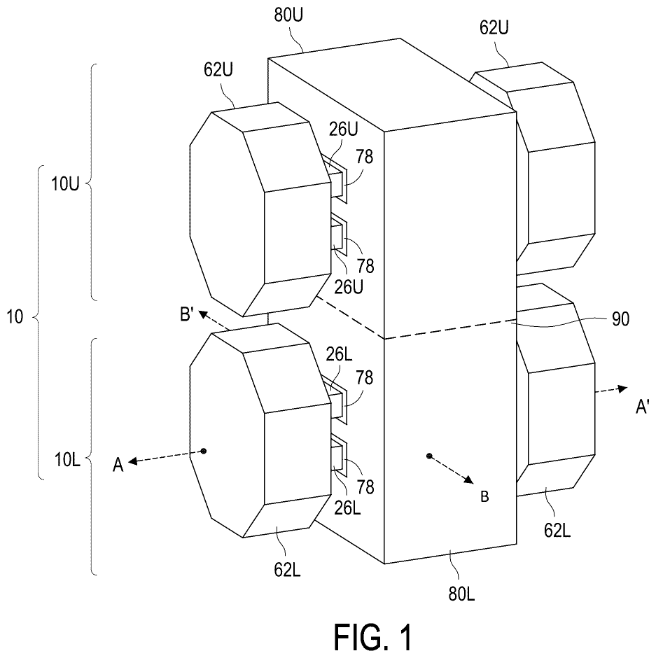

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Cross-section B-B′ is a vertical cross-section that is perpendicular to cross-section A-A′ and along a longitudinal axis of a gate electrode 80 of the stacking transistor. Subsequent figures may refer to these reference cross-sections for clarity.

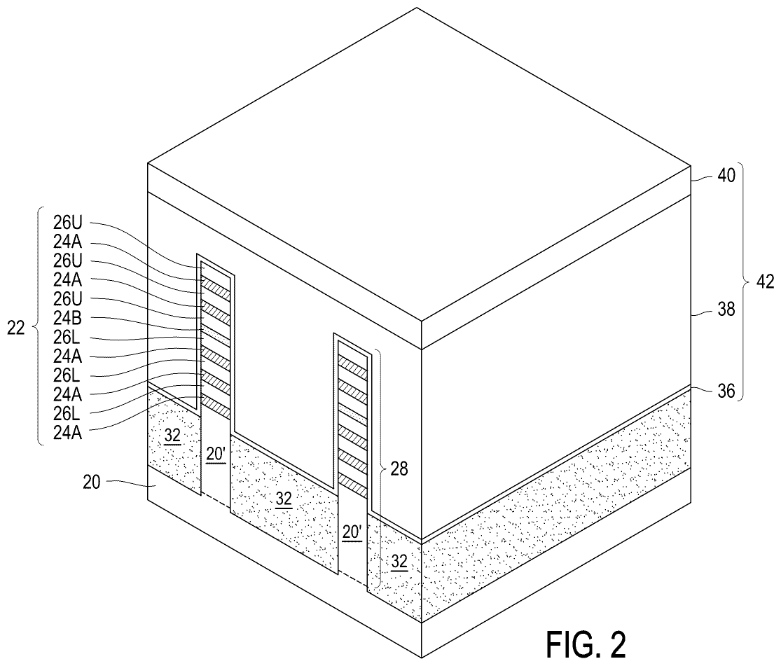

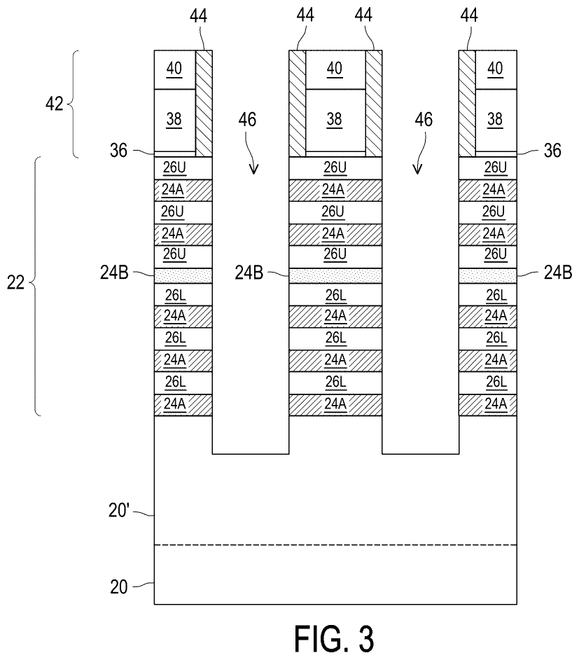

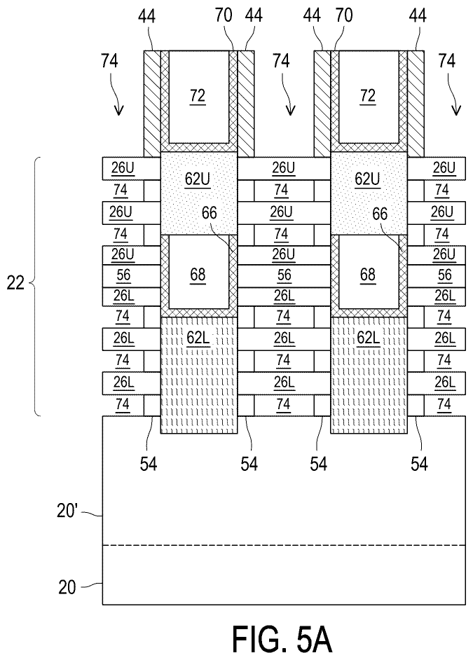

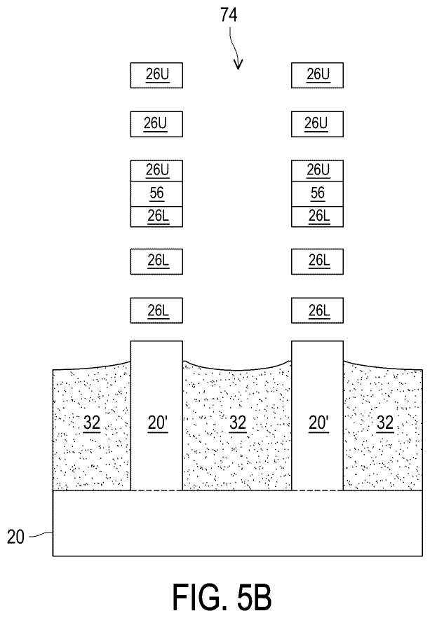

FIGS. 2 through 11 illustrate the cross-sectional views of intermediate stages in the formation of stacking transistors (as schematically represented in FIG. 1) in accordance with some embodiments. FIG. 2 provides a perspective view similar to FIG. 1. FIGS. 3, 4, 5A, and 11 illustrate the vertical cross-sectional views along a similar cross-section as vertical reference cross-section A-A′ in FIG. 1. FIGS. 5B, 6, 7, 8, 9, and 10 illustrate the cross-sectional views along a similar cross-section as the vertical reference cross-section B-B′ in FIG. 1.

Various embodiments are described below in a specific context, namely, depositing a gate material (e.g., a WFM) in a stacking transistor having stacked nanostructure-FETs. In other embodiments, the stacking transistors may have a different type of transistor (e.g., finFETs). In still other embodiments, the described gap fill methods may be applied to fill any trench or opening and are not limited to forming gate structures. For example, embodiment gap fill methods may be applied to forming interconnect structures, contact structures, or the like, including filling conductive via openings, conductive line trench openings, sheet spacing, holes, or the like. The surface material (e.g., substrate) on which the embodiment gap fill methods deposit metal layers on can be any suitable material such as dielectric materials (e.g., HfO₂, ZrO₂, TiO₂, SiO₂, SiN) or nonconductive materials (e.g., silicon, germanium, silicon germanium, doped silicon, or the like). Embodiments may be used to deposit gate materials (e.g., work function metal (WFM) layer) for gate stacks as described below, but embodiments may also be used to deposit any type of target metal. For example, embodiments may be applied to forming a pure metal (e.g., W, Mo, Pt, Pd, Co, Ru, Rh, Ag, Au, Cu, Ni, Fe, Ti, or the like), an alloy (e.g., TiN, NiB, NiP, CONiP, CONiB, CoMnP, CoNiMnP, CoWP, CoWB, CoNiReP, CoB. CoP, CoFeB, CoNiFeB, FeP, or the like), combinations thereof, or the like. Thus, it should be understood that various embodiments are not limited to the specific context described below.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. As a specific example, the dummy semiconductor nanostructures 24A are formed of silicon germanium, the semiconductor layers 26 are formed of silicon, and the dummy semiconductor nanostructures 24B may be formed of germanium or silicon germanium with a higher germanium atomic percentage than the semiconductor nanostructures 24A. Other combinations of semiconductor materials are also possible for the dummy semiconductor nanostructures 24A, the dummy semiconductor nanostructures 24B, and the semiconductor nanostructures 26.

The lower semiconductor nanostructures 26L will provide channel regions for lower nanostructure-FETs of the stacking transistors. The upper semiconductor nanostructures 26U will provide channel regions for upper nanostructure-FETs of the stacking transistors. The semiconductor nanostructures 26 that are immediately above/below (e.g., in contact with) the dummy nanostructures 24B may be used for isolation and may or may not act as channel regions for the stacking transistors. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the STI regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

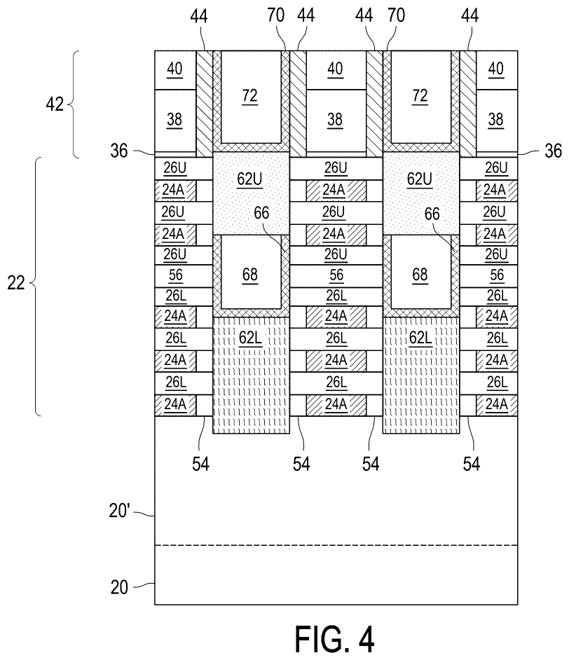

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the second ILD 68.

FIG. 5A through 10 illustrates a replacement gate process to replace the dummy gate stacks 42 and the dummy nanostructures 24A with gate stacks 90. Referring first to FIGS. 5A and 5B, the replacement gate process includes first removing the dummy gate stacks 42 and the remaining portions of the dummy nanostructures 24A to define gate openings 74. FIG. 5A illustrates a cross-sectional view along cross-section A-A of FIG. 1, and FIG. 5B illustrates a cross-sectional view along cross-section B-B of FIG. 1. The dummy gate stacks 42 are removed in one or more etching processes, so that the gate openings 74 are defined between the gate spacers 44 and the upper portions of the semiconductor strips 28 are exposed. The remaining portions of the dummy nanostructures 24A are then removed through etching, so that the gate openings 74 extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

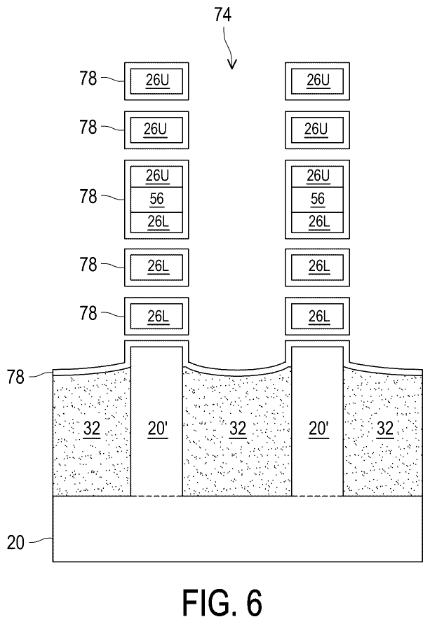

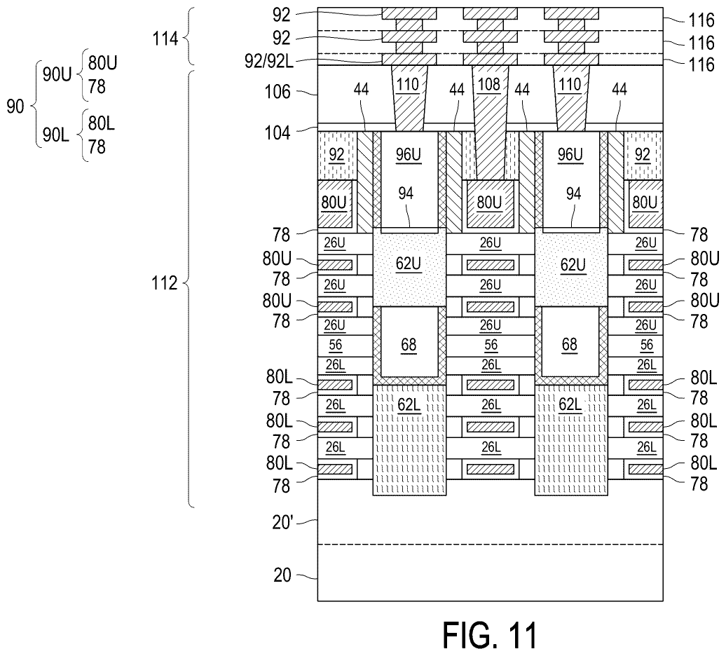

Then, in FIG. 6, gate dielectrics 78 are deposited in the recesses between the gate spacers 44 (see FIG. 11) and on the exposed semiconductor nanostructures 26. The gate dielectrics 78 are conformally formed on the exposed surfaces of the gate openings 74 including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26. The gate dielectrics 78 may also be formed on the sidewalls of the gate spacers 90 (see FIG. 11). The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

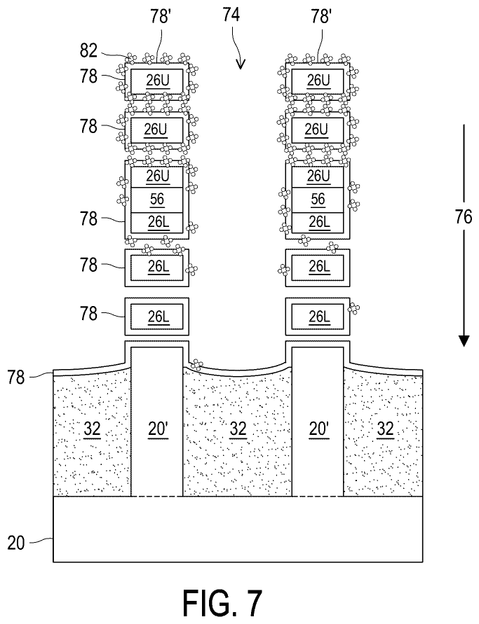

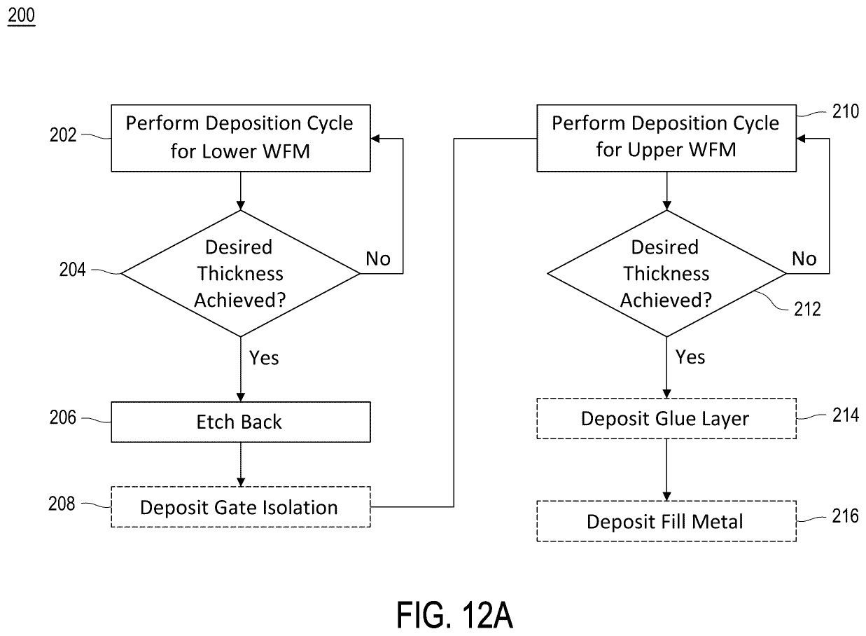

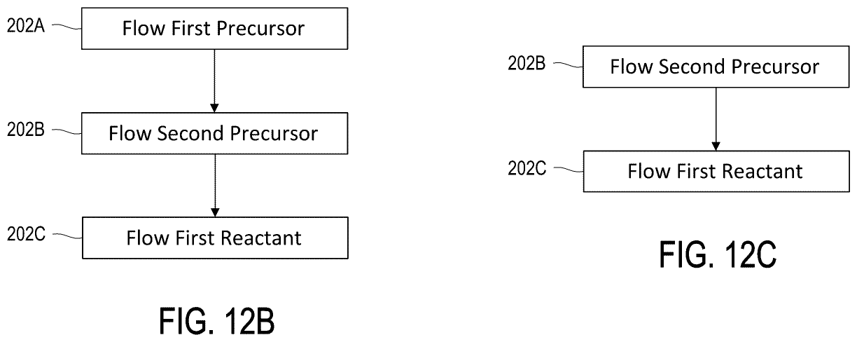

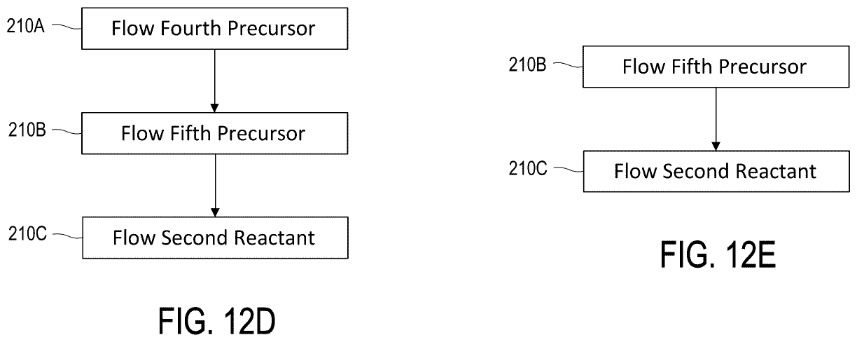

In FIGS. 7 through 10, lower gate electrodes 80L and upper gate electrodes 80U are formed around the around the lower semiconductor nanostructures 26L and the upper nanostructures 26U, respectively. FIGS. 12A through 12E provide flow diagrams for forming the lower gate electrodes 80L and the upper gate electrodes 80U according to various embodiments.

The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L are formed of material(s) that are suitable for the device type of the lower nanostructure-FETs. For example, the lower gate electrodes 80L may include one or more work function metal (WFM) layer(s) formed of material(s) that are suitable for the device type of the lower nanostructure-FETs. In some embodiments, the lower gate electrodes 80L include an n-type WFM layer, which may be formed of titanium aluminum, titanium aluminum carbide, tantalum aluminum, tantalum carbide, combinations thereof, or the like. In some embodiments, the lower gate electrodes 80L include a p-type WFM layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). For example, a lower WFM layer of the lower gate electrodes 80L may be formed around the semiconductor nanostructures 26 according to steps 202 and 204 of FIG. 12A. Depositing the lower WFM layer may include a conformal deposition process, such as, CVD, ALD, a combination thereof, or the like. As indicated by steps 202 and 204 of FIG. 12A, the conformal deposition process may include performing N deposition cycles until a desired thickness for the lower WFM layer is achieved, where N is any positive integer. The conformal deposition may be a bottom-up deposition process as described in greater detail below. In some embodiments, an optional inhibitor (e.g., a self assembled monolayer (SAM) or small molecule inhibitor (SMI)) may be formed to cover the top surfaces (e.g., surfaces 78′ of FIG. 7) of the gate dielectrics 78 prior to conformal deposition process to further promote the bottom-up directionality of the conformal deposition process. After the conformal deposition process is completed, an optional annealing process may be performed. For example, the lower WFM layer may be annealed at a temperature in a range of 200° C. to 600° C. in an inert gas (e.g., Ar, He, N₂, or the like) environment.

The N deposition cycles will now be described with respect to FIGS. 7 through 9, 12B, and 12C. FIG. 12B illustrates a process flow of an initial deposition cycle of the conformal deposition process for depositing the lower gate electrodes 80L (e.g., depositing a lower WFM layer of the lower ate electrodes 80L). Referring first to step 202A of FIG. 12B and FIG. 7, a first precursor 82 is flowed into the gate openings 74 over the gate dielectrics 78. The first precursor 82 may be selected from metal organic compounds, metal halides, metal carbonyls, metal complex, or the like with a relatively high sticking coefficient. For example, the first precursor 82 may be a metal halide. In embodiments where the target metal layer (e.g., the lower WFM layer) is a titanium nitride layer, the first precursor 82 may be TiCl₄. Due to the relatively high sticking coefficient of the first precursor 82, the first precursor may accumulate and attach to upper surfaces and upper sidewalls in the gate opening 74 (e.g., upper surfaces and sidewalls of the gate dielectric 78). A surface concentration of the first precursor 82 may decrease along a direction of arrow 76 towards the bottom of the gate opening 74/the substrate 20. For example, the first precursor 82 may fully saturate the upper surfaces and upper sidewalls of the gate dielectric 78, and a saturation percentage of the first precursor 82 may decrease to substantially zero at the bottom surface of the gate openings 74. A depth and coverage profile of the first precursor 82 may be controlled by controlling one or more processing parameters (e.g., precursor dosage, precursor flow time, or the like) while flowing the first precursor 82. After the first precursor 82 is flowed into the chamber, a gas purge may be performed with an inert gas (e.g., Ar, He, N₂, or the like) to remove excess (e.g., unattached) amounts of the first precursor 82 from the processing chamber.

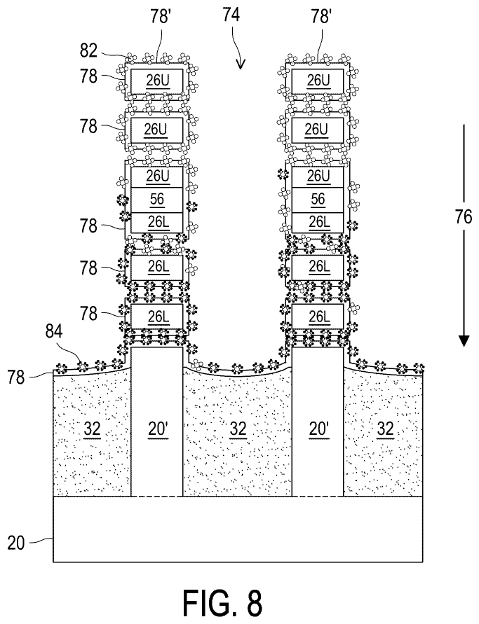

Next, referring to step 202B of FIG. 12B and FIG. 8, a second precursor 84 is flowed into the gate openings 74, such as over the gate dielectrics 78. The second precursor 84 may be selected from metal organic compounds, metal halides, metal carbonyls, metal complex, or the like with a relatively low sticking coefficient. In some embodiments, the first and second precursors 82 and 84 are both selected from candidate precursors for forming a same, target metal (e.g., the material of the lower WFM layer), and the first and second precursors 82 and 84 do not react with each other. For example, the second precursor 84 may be a metal carbonyl. In embodiments where the target metal layer (e.g., the lower WFM layer) is a titanium nitride layer, the second precursor 84 may be tetrakis (dimethylamino) titanium (TDMAT). Due to the top surfaces in the gate openings 74 being substantially occupied by the first precursor 82, the second precursor 84 may flow towards bottoms of the gate openings 74 and attach to lower surfaces and lower sidewalls in the gate openings 74 (e.g., lower surfaces and sidewalls of the gate dielectric 78). The relatively low sticking coefficient of the second precursor 84 may further promote the flow of the second precursor 84 towards the bottom of the gate openings 74 as the second precursor 84 will not tend to accumulate on upper surfaces of the gate openings 74. A surface concentration of the second precursor 84 may increase along a direction of arrow 76 towards the bottom of the gate openings 74/the substrate 20. For example, the second precursor 84 may fully saturate the lower surfaces and lower sidewalls of the gate openings 74, and a saturation percentage of the first precursor 82 may decrease to substantially zero at the top of the gate openings 74.

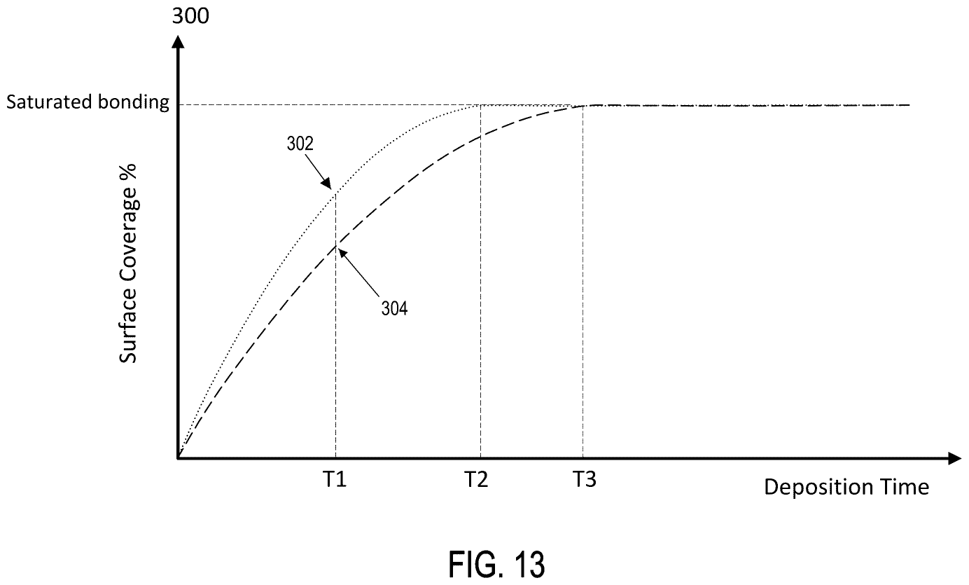

The first precursor 82 may have a higher sticking coefficient than the second precursor 84. FIG. 13 illustrates differences in the sticking coefficients between the first precursor 82 and the second precursor 84 according to various embodiments. Specifically, FIG. 13 illustrates a graph 300 of surface coverage percentage achieved by flowing a precursor over a blanket substrate as a function of time. Line 302 corresponds to the coverage of the first precursor 82, and line 304 corresponds to the coverage of the second precursor 84. As can be seen from graph 300 at time T1, neither the first precursor 82 (as indicated by line 302) nor the second precursor 84 (as indicated by line 304) can achieve 100% surface converge (sometimes referred to as saturated bonding). However, a surface coverage percentage of the first precursor 82 may be higher than a surface coverage percentage of the second precursor 84 at the time T1. Subsequently at time T2, the first precursor 82 may achieve saturation on the blanket substrate, while the second precursor 84 has not yet achieved saturation on the blanket substrate. At time T3 after the time T2, both the first precursor 82 and the second precursor 84 have achieved saturation on the blanket substrate. As can be seen by FIG. 13, the relatively high sticking coefficient of the first precursor 82 compared to the relatively low sticking coefficient of the second precursor 84 allows the first precursor 82 to attach to surfaces at a faster rate and reach surface saturation faster than the second precursor 84. As a result, the first precursor 82 is more likely to stick to upper surfaces of the gate openings 74, and the second precursor 84 can be subsequently flowed into the gate openings 74 to cover remaining surfaces (lower surfaces) of the gate openings 74. In some embodiments, the flow time of the first precursor 82 may be less than T2 so that the first precursor 82 only partially saturates surfaces of the gate openings 74 while the flow time of the second precursor 84 may be greater than T3 so that remaining surfaces of the gate openings 74 are fully saturated by the second precursor 84. For example, the second precursor 84 may be overdosed in the gate openings 74 so that surfaces of the gate openings 74 are fully saturated by the first and second precursors 82 and 84.

After the second precursor 84 is flowed into the chamber for a desired time to achieve a desired surface coverage, a gas purge may be performed with an inert gas (e.g., Ar, He, N₂, or the like) to remove excess (e.g., unattached) amounts of the first precursor 82 from the processing chamber. As a result, the surfaces of gate openings 74 may have a mono-layer of precursor coverage from a combination of the first precursor 82 (at the tops of the openings 74) and the second precursor 84 (at the bottoms of the openings 74).

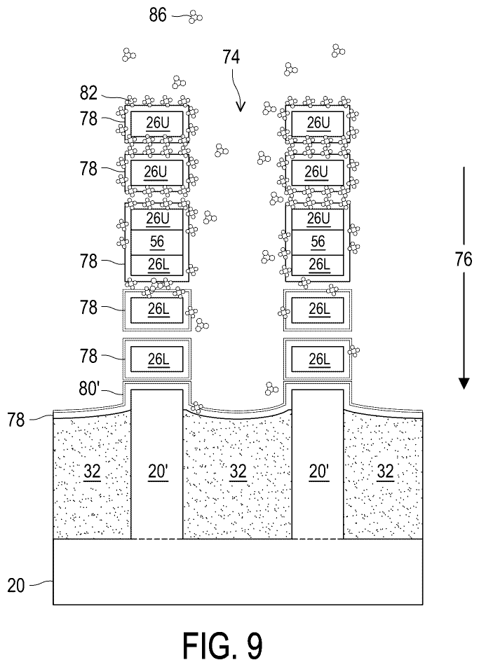

Next, referring to step 202C of FIG. 12B and FIG. 9, a first reactant 86 (sometimes referred to as a third precursor) is flowed into the gate openings 74, such as over the monolayer of the first and second precursors 82 and 84. The reactant may be selected from a material that reacts with the first and second precursors 82 and 84 to form a portion (e.g., a monolayer) of the target metal layer 80′ (e.g., the lower WFM layer). For example, where the target metal layer is a titanium nitride layer, the first precursor 82 is TiCl₄, the second precursor 84 is TDMAT, and the first reactant 86 may be ammonia (NH₃) or hydrazine (N₂H₄). A process condition for flowing the first reactant 86 can be controlled such that the first reactant 86 reacts with the second precursor 84 at a greater rate than with the first precursor 82. For example, a temperature of the processing chamber while flowing the first reactant 86 may be controlled to promote reactions between the second precursor 84 and the first reactant 86 while limiting reactions between the first precursor 82 and the first reactant 86. In some embodiments, the temperature of the processing chamber while flowing the first reactant 86 may be in a range of 300° C. to 350° C. to promote the reactions between the second precursor 84 and the first reactant 86 while limiting reactions between the first precursor 82 and the first reactant 86. Other processing conditions that may be controlled include the presence or absence of plasma, the presence or absence of ion beams, and/or the presence of a reagent that is selective to the first precursor 82 while flowing the first reactant 86. In various embodiments, the materials of the first precursor 82 and the second precursor 84 may also be selected so that a selective reaction can be achieved when flowing the first reactant 86 by controlling the one or more of the processing parameters discussed above. As a result, the portion of the target metal layer 80′ may be formed substantially in the bottoms of the gate openings 74′, and the target metal layer 80′ may not be formed or only have limited formation at tops of the gate openings 74′. The first precursor 82 at top surfaces in the gate openings 74′ may act as a self-inhibition reagent that reduces the formation of the target metal layer 80′ at tops of the gate openings 74′. For example, the first precursors 82 may limit growth of the target metal layer 80′ at the tops of the gate openings 74′ such that the target metal layer 80′ is primarily formed in the bottoms of the gate openings 74′. Subsequently, a gas purge may be performed with an inert gas (e.g., Ar, He, N₂, or the like) to remove excess (e.g., unreacted) amounts of the first reactant 86 from the processing chamber.

Thus, an initial cycle of the deposition process for forming a layer of the lower gate electrode 80L is completed. The process for forming the lower gate electrode 80L may continue by performing additional deposition cycle for the lower WFM layer (steps 202 and 204 of FIG. 12A) until a desired thickness of the lower WFM layer is achieved. Each deposition cycle may be according to at least the process flow of FIG. 12C where the second precursor 84 is flowed over the target metal layer 80′ (step 202B), and the first reactant 86 is then flowed to react with the second precursor 84 and form additional portions (e.g., monolayers) of the target metal layer 80′. In some embodiments, a grain boundary may be observed between portions of the target metal layer 80′ that is formed in different deposition cycles. After the initial deposition cycle, the second precursor 84 may attach to and saturate exposed surfaces of the target metal layer 80′ that was formed in previous deposition cycles. In this manner, the target metal layer 80′ (e.g., the lower WFM layer) of the lower gate electrode can be deposited in a bottom-up seamless process. The first reactant 86 may also slowly react with the first precursor 82 albeit at a slower rate than with the second precursor 84. For example, the first reactant 86 may react with the first precursor 82 across multiple deposition cycles to form a single deposition cycle's amount (e.g., monolayer) of the target metal layer 80′. In this manner, over the course of multiple cycles, the bottom up deposition process may grow the target metal layer 80′ (e.g., the lower WFM layer of the lower gate electrode 80L) from the bottom of gate openings 74 to the top of the gate openings 74.

In some embodiments, the first precursor 82 may also be flowed in one or more of the subsequent deposition cycles to reduce a growth rate of the target metal layer 80′ at tops of the gate openings 74. For example, each deposition cycle for the lower WFM layer may be according to either the process flow of FIG. 12B where the first precursor 82, the second precursor 84, and the first reactant 86 are sequentially flowed or the process flow of FIG. 12C where the first precursor 82 is omitted and only the second precursor 84 and the first reactant 86 are flowed. The first precursor 82 may be flowed every other deposition cycle, every third deposition cycle, or the like.

In some embodiments, the lower gate electrode 80L may be deposited to completely fill or overfill the gate openings 74. In some embodiments, the lower gate electrode 80L may be deposited to partially fill the gate openings 74, but the lower gate electrode 80L may be deposited to an unacceptably high level. For example, the lower gate electrode 80L may be deposited around the upper semiconductor nanostructures 26U as well as the lower semiconductor nanostructures 26L. Thus, after one or more layers of the lower gate electrode 80L is deposited, an etch-back process may be performed in step 206 of FIG. 12A to recess the lower gate electrode 80L to a level below the upper semiconductor nanostructures 26U. Any acceptable etch process, such as a dry etch, a wet etch, the like, or a combination thereof, may be performed to recess the gate electrode layer(s) of the lower gate electrode 80L. The etching may be isotropic or anisotropic. Due to the seam-less bottom-up deposition process used to form the lower gate electrode 80L, the etch-back process may be performed with improved control, such as improved depth control. As a result, the profile of the etched back, lower gate electrode 80L may be improved. Etching the lower gate electrodes 80L may remove portions of the lower gate electrodes 80L around the upper semiconductor nanostructures 26U and expose the upper semiconductor nanostructures 26U. In embodiments where the lower gate electrode 80L is deposited to overfill the gate openings 74, a planarization process (e.g., CMP) may be performed prior to the etching process. In such embodiments, the planarization process removes portions of the lower gate electrode 80L that are deposited over the gate openings 74.

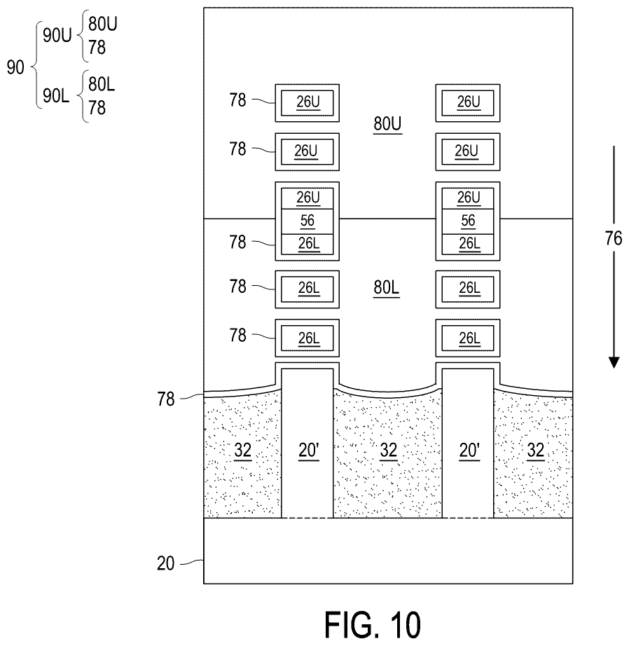

In some embodiments, isolation layers (not explicitly illustrated) may be optionally formed on the lower gate electrodes 80L as illustrated by step 208 of FIG. 12A. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U. The resulting structure is illustrated in FIG. 10.

Then, upper gate electrodes 80U are formed on the isolation layers described above (if present) or the lower gate electrodes 80L (steps 210 and 212 of FIG. 12A). The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. In embodiments where the stacking transistors are CFET devices, a device type of the upper gate electrodes 80U may be opposite from a device type of the lower gate electrodes 80L. For example, the upper gate electrodes 80U may be n-type while the lower gate electrodes 80L are p-type, or the upper gate electrodes 80U may be p-type while the lower gate electrodes 80L are n-type. Although single-layered gate electrodes 80U are illustrated, the upper gate electrodes 80U may include any number of WFM layers and/or any number of barrier layers.

In various embodiments, the layer(s) of the upper gate electrode 80U may be deposited using a bottom-up deposition process similar to those described above with respect to the lower gate electrode 80L. For example, an upper WFM layer of the gate electrode 80U may be deposited with a conformal deposition process, such as ALD, CVD, or a combination thereof. The conformal deposition process may include performing M deposition cycles until a desired thickness for the lower WFM layer is achieved, where M is any positive integer (steps 210 and 212 of FIG. 12A). The conformal deposition may be a bottom-up deposition process similar as that described above with respect to depositing the lower gate electrode 80L. In some embodiments, an optional inhibitor (e.g., a self assembled monolayer (SAM) or small molecule inhibitor (SMI)) may be formed to cover the top surfaces of the gate dielectrics 78 prior to conformal deposition process to further promote the bottom-up directionality of the conformal deposition process. After the conformal deposition process is completed, an optional annealing process may be performed. For example, the upper WFM layer may be annealed at a temperature in a range of 200° C. to 600° C. in an inert gas (e.g., Ar, He, N₂, or the like) environment.

An initial deposition of the M deposition cycles for forming the upper WFM layer of the upper gate electrodes 80U may be according to the process described in FIG. 12D. For example, the initial deposition process may include sequentially flowing a fourth precursor (analogous to the first precursor 82 described above) with a relatively high sticking coefficient, a fifth precursor (analogous to the second precursor 84 described above) with a relatively low sticking coefficient, and a second reactant (analogous to the first reactant 86 described above, also referred to as a sixth precursor in some embodiments). In a specific embodiment, the fourth precursor is a metal halide, and the fifth precursor is a metal carbonyl. The fourth precursor attaches to the upper surfaces in the gate openings 74, and the fifth precursor attaches to lower surfaces in the gate openings 74 (e.g., the upper surfaces of the lower gate electrode 80L) according to the mechanisms described above in FIGS. 7 and 8. The second reactant then is flowed into react with the fifth precursor at a greater rate than the fourth precursor according to the mechanisms described above in FIG. 9. Following the initial deposition cycle, each subsequent deposition cycle for the upper WFM layer may be according to either the process flow of FIG. 12D where the fourth precursor, the fifth precursor, and the second reactant are sequentially flowed or the process flow of FIG. 12E where the fourth precursor is omitted and only the fifth precursor and the second reactant are flowed. The fourth precursor may be flowed every other deposition cycle, every third deposition cycle, or the like. In this manner, layers of the upper gate electrodes 80U may be grown in a bottom-up seamless deposition process for improved electrical performance (e.g., lower resistance).

In some embodiments, only the WFM layers of the lower gate electrodes 80L and the upper gate electrodes 80U are deposited using the above processes. Subsequently, an optional glue layer (step 214 of FIG. 12A) and a fill metal (step 216) are deposited over the upper and lower WFM layers. The glue later and the fill metal may be formed by any conformal deposition process, such as CVD, ALD, combinations thereof or the like. The deposition process for forming the glue layer and the fill metal may or may not be according to the bottom-up seamless process described above.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. In embodiments where the planarization process includes an etch-back process, any acceptable etch process, such as a dry etch, a wet etch, the like, or a combination thereof, may be performed to recess the gate electrode layer(s) of the upper gate electrodes 80U. The etching may be isotropic or anisotropic. Due to the seam-less bottom-up deposition process used to form the upper gate electrodes 80U, the etch-back process may be performed with improved control, such as improved depth control. As a result, the profile of the etched back, upper gate electrodes 80U may be improved. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

Because both a first and a second precursor are used to form at least the WFM layers of the lower gate electrodes 80L and/or a fourth precursor and a fifth precursor are used to form at least the WFM layers of the upper gate electrodes 80U, precursor residue from each of the first precursor 82 (and the analogous fourth precursor) and the second precursor 84 (and the analogous fifth precursor) may remain in the lower gate electrodes 80L and the upper gate electrodes 80U. The precursor residue may include a halogen (e.g., chlorine), carbon, oxygen, nitrogen, or the like, a concentration of the precursor residue may vary and have a gradient along the arrow 76. For example, when metal halides are used as the first precursor 82 (or the fourth precursor), a concentration of the halide residue (e.g., Cl) in the lower gate electrode 80L (and/or the upper gate electrode 80U) may decrease in a direction along the arrow 76 towards the substrate 20. As another example, when metal carbonyls are used as the second precursor 84 (or the fifth precursor), a concentration of the carbonyl residue (e.g., carbon and/or oxygen) in the lower gate electrode 80L (and/or the upper gate electrode 80U) may increase in a direction along the arrow 76 towards the substrate 20.

Referring next to FIG. 11, gate masks 92 are formed over the gate stacks 90. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

Metal-semiconductor alloy regions 94 and source/drain contacts 96 are then formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 62L may be made through a backside of the device layer 112 (e.g., a side opposite to the front-side interconnect structure 114).

In some embodiments, a method of forming a semiconductor device includes forming an opening in a semiconductor device and depositing a target metal layer in the opening, wherein depositing the target metal layer comprises performing a plurality of deposition cycles. An initial deposition cycle of the plurality of deposition cycles includes flowing a first precursor in the opening, wherein the first precursor attaches to upper surfaces in the opening; after flowing the first precursor, flowing a second precursor in the opening, wherein the second precursor attaches to remaining surfaces in the opening, and wherein the first precursor does not react with the second precursor; and flowing a reactant in the opening, wherein the reactant reacts with the second precursor at a greater rate than the reactant reacts with the first precursor. Optionally, in some embodiments, the first precursor has a greater sticking coefficient than the second precursor. Optionally, in some embodiments, the first precursor is a metal halide, and the second precursor is a metal carbonyl. Optionally, in some embodiments, after flowing the first precursor, a concentration of the first precursor decreases along a direction towards a bottom of the opening. Optionally, in some embodiments, after flowing the second precursor, a concentration of the second precursor increases along a direction towards a bottom of the opening. Optionally, in some embodiments, the method further includes controlling a process parameter while flowing the reactant such that the reactant reacts with the second precursor at a greater rate than the reactant reacts with the first precursor. Optionally, in some embodiments, the process parameter comprises a process temperature, a presence or absence of plasma, a presence or absence of an ion beam, a presence of a reagent that is selective to the first precursor, or a combination thereof. Optionally, in some embodiments, each subsequent deposition cycle of the plurality of deposition cycles after the initial deposition cycle comprises: flowing the second precursor in the opening; and flowing the reactant in the opening. Optionally, in some embodiments, a subsequent deposition cycle of the plurality of deposition cycles after the initial deposition cycle comprises: prior to flowing the second precursor in the opening, flowing the first precursor in the opening. Optionally, in some embodiments, the initial deposition cycle further comprises: performing a first inert gas purge between flowing the first precursor and lowing the second precursor; performing a second inert gas purge between flowing the second precursor and flowing the reactant; and performing a third inert gas purge after flowing the reactant.

In some embodiments, a method includes forming a dummy gate stack around a plurality of nanostructures over a substrate, wherein the plurality of nanostructures are alternatingly stacked with a plurality of dummy nanostructures; forming lower source/drain regions over the substrate, wherein lower nanostructures of the plurality of nanostructures extend between the lower source/drain regions; forming upper source/drain regions over the lower source/drain regions, wherein upper nanostructures of the plurality of nanostructures extend between the upper source/drain regions; removing the dummy gate stack and the plurality of dummy nanostructures to define an opening; and performing a first deposition process to form a lower work function metal (WFM) layer in the opening around the plurality of nanostructures. An initial deposition cycle of the first deposition process comprises: flowing a first precursor in the opening, wherein the first precursor attaches to upper surfaces in the opening; after flowing the first precursor, flowing a second precursor in the opening, wherein the second precursor attaches to lower surfaces in the opening, and wherein the first precursor has a higher sticking coefficient than the second precursor; and flowing a third precursor in the opening, wherein the third precursor reacts with the second precursor at a greater rate than the third precursor reacts with the first precursor. Optionally, in some embodiments, the method further includes recessing the lower WFM layer in the opening; and performing a second deposition process to form an upper WFM layer in the opening around the upper nanostructures and over the lower WFM layer. Optionally, in some embodiments, an initial deposition cycle of the second deposition process comprises: flowing a fourth precursor in the opening, wherein the fourth precursor attaches to upper surfaces in the opening; after flowing the fourth precursor, flowing a fifth precursor in the opening, wherein the fifth precursor attaches to remaining surfaces in the opening, and wherein the fourth precursor has a higher sticking coefficient than the fifth precursor; and flowing a sixth precursor in the opening, wherein the sixth precursor reacts with the fifth precursor at a greater rate than the sixth precursor reacts with the fourth precursor. Optionally, in some embodiments, the method further includes depositing a glue layer over the upper WFM layer; and depositing a fill metal over the glue layer. Optionally, in some embodiments, the first precursor is a metal halide, and wherein the second precursor is a metal carbonyl. Optionally, in some embodiments, the lower WFM layer comprises titanium nitride, wherein the first precursor is TiCl₄, wherein the second precursor is tetrakis(dimethylamino) titanium (TDMAT), and wherein the third precursor is NH₃ or N₂H₄. Optionally, in some embodiments, each subsequent deposition cycle of the first deposition process after the initial deposition cycle of the first deposition process comprises: flowing the second precursor in the opening; and flowing the third precursor in the opening.

In some embodiments, a semiconductor device includes lower nanostructures extending between lower source/drain regions; upper nanostructures extending between upper source/drain regions, wherein the upper nanostructures is disposed over the lower nanostructures, and wherein the upper source/drain regions is disposed over the lower source/drain regions; a lower gate electrode around the lower nanostructures, wherein the lower gate electrode comprises a halide residue, and wherein a concentration of halide residue in the lower gate electrode decreases in a direction towards a bottom surface of the lower gate electrode; and an upper gate electrode around the upper nanostructures, wherein the upper gate electrode is disposed over the lower gate electrode. Optionally, in some embodiments, the lower gate electrode further comprises a carbonyl residue, and wherein a concentration of the carbonyl residue increases in a direction towards the bottom surface of the lower gate electrode. Optionally, in some embodiments, the halide residue is chlorine, and wherein the carbonyl residue is carbon or oxygen.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a stack of nanostructures, the stack of nanostructures comprising upper nanostructures over lower nanostructures; and
depositing a first metal layer around the stack of nanostructures, wherein depositing the first metal layer comprises performing a plurality of deposition cycles, and wherein an initial deposition cycle of the plurality of deposition cycles comprises:
flowing a first precursor over the stack of nanostructures, wherein the first precursor attaches to the upper nanostructures;
after flowing the first precursor, flowing a second precursor over the stack of nanostructures, wherein the second precursor attaches to the lower nanostructures, and wherein the first precursor does not react with the second precursor; and
flowing a reactant over the stack of nanostructures, wherein the reactant reacts with the second precursor at a greater rate than the reactant reacts with the first precursor.

2. The method of claim 1, wherein the first precursor has a greater sticking coefficient than the second precursor.

3. The method of claim 1, wherein the first precursor is a metal halide, and the second precursor is a metal carbonyl.

4. The method of claim 1, wherein a saturation percentage of the first precursor on surfaces the upper nanostructures is greater than a saturation percentage of the first precursor on surfaces of the lower nanostructures during the initial deposition cycle.

5. The method of claim 1, wherein a saturation percentage of the second precursor on surfaces the upper nanostructures is less than a saturation percentage of the second precursor on surfaces of the lower nanostructures during the initial deposition cycle.

6. The method of claim 1 further comprising controlling a process parameter while flowing the reactant such that the reactant reacts with the second precursor at a greater rate than the reactant reacts with the first precursor.

7. The method of claim 6, wherein the process parameter comprises a process temperature, a presence or absence of plasma, a presence or absence of an ion beam, a presence of a reagent that is selective to the first precursor, or a combination thereof.

8. The method of claim 1, wherein each subsequent deposition cycle of the plurality of deposition cycles after the initial deposition cycle comprises:
flowing the second precursor over the stack of nanostructures, wherein the second precursor attaches to portions of the first metal layer previously deposited on the stack of nanostructures; and
flowing the reactant over the stack of nanostructures.

9. The method of claim 8, wherein each subsequent deposition cycle of the plurality of deposition cycles after the initial deposition cycle comprises:
prior to flowing the second precursor over the stack of nanostructures, flowing the first precursor over the stack of nanostructures, wherein the first precursor attaches to the upper nanostructures.

10. The method of claim 1, wherein the initial deposition cycle further comprises:
performing a first inert gas purge between flowing the first precursor and flowing the second precursor;
performing a second inert gas purge between flowing the second precursor and flowing the reactant; and
performing a third inert gas purge after flowing the reactant.

11. A method comprising:
forming a dummy gate stack around a plurality of nanostructures over a substrate, wherein the plurality of nanostructures are alternatingly stacked with a plurality of dummy nanostructures;
forming lower source/drain regions over the substrate, wherein lower nanostructures of the plurality of nanostructures extend between the lower source/drain regions;
forming upper source/drain regions over the lower source/drain regions, wherein upper nanostructures of the plurality of nanostructures extend between the upper source/drain regions;
removing the dummy gate stack and the plurality of dummy nanostructures to define an opening; and
performing a first bottom-up deposition process to form a lower work function metal (WFM) layer in the opening around the plurality of nanostructures, wherein at least one deposition cycle of the first bottom-up deposition process comprises:
flowing a first precursor in the opening, wherein a saturation percentage of the first precursor on surfaces the upper nanostructures is greater than a saturation percentage of the first precursor on surfaces of the lower nanostructures;
flowing a second precursor in the opening, wherein a saturation percentage of the second precursor on the surfaces the upper nanostructures is less than a saturation percentage of the second precursor on the surfaces of the lower nanostructures; and
reacting the second precursor in the opening with a first reactant, wherein the first reactant reacts with the second precursor at a greater rate than the first reactant reacts with the first precursor; and
performing a second deposition process to form an upper WFM layer in the opening around the upper nanostructures.

12. The method of claim 11 further comprising:
recessing the lower WFM layer in the opening to a level below the upper nanostructures prior to performing the second deposition process, wherein the second deposition process is a bottom-up deposition process; and
depositing a fill metal over the upper WFM layer.

13. The method of claim 12, wherein at least one deposition cycle of the second deposition process comprises:
flowing a third precursor in the opening, wherein a saturation percentage of the third precursor on upper surfaces the upper nanostructures is greater than a saturation percentage of the third precursor on lower surfaces of the upper nanostructures;
flowing a fourth precursor in the opening, wherein a saturation percentage of the fourth precursor on the upper surfaces the upper nanostructures is less than a saturation percentage of the fourth precursor on the lower surfaces of the upper nanostructures; and
flowing a second reactant in the opening, wherein the second reactant reacts with the fourth precursor at a greater rate than the second reactant reacts with the third precursor.

14. The method of claim 11, wherein a second deposition cycle of the first bottom-up deposition process comprises flowing the second precursor into the opening without flowing the first precursor into the opening, and flowing the first reactant in the opening.

15. The method of claim 11, wherein the first precursor is a metal halide, and wherein the second precursor is a metal carbonyl.

16. The method of claim 15, wherein the lower WFM layer comprises titanium nitride, wherein the first precursor is TiCl₄, wherein the second precursor is tetrakis(dimethylamino) titanium (TDMAT), and wherein the first reactant is NH₃ or N₂H₄.

17. A method of forming a semiconductor device, the method comprising:
forming a stack of nanostructures, the stack of nanostructures comprising upper nanostructures over lower nanostructures;
depositing a gate dielectric around the stack of nanostructures; and
depositing a first metal layer over the gate dielectric and around the stack of nanostructures, wherein depositing the first metal layer comprises performing a plurality of deposition cycles, and wherein a first deposition cycle of the plurality of deposition cycles comprises:
flowing a first precursor over the stack of nanostructures, wherein the first precursor attaches to the upper nanostructures;
flowing a second precursor over the stack of nanostructures, wherein the second precursor attaches to the lower nanostructures, wherein the first precursor has a greater sticking coefficient than the second precursor; and
reacting the second precursor with a reactant while controlling a process parameter such that the reactant reacts with the second precursor at a greater rate than the reactant reacts with the first precursor.

18. The method of claim 17, wherein controlling the process parameter comprises controlling a temperature while flowing the reactant to be within a range of 300° C. to 350° C.

19. The method of claim 17, wherein:
a saturation percentage of the first precursor on surfaces the upper nanostructures is greater than a saturation percentage of the first precursor on surfaces of the lower nanostructures during the first deposition cycle; and
a saturation percentage of the second precursor on the surfaces the upper nanostructures is less than a saturation percentage of the second precursor on the surfaces of the lower nanostructures during the first deposition cycle.

20. The method of claim 17, wherein the first precursor and the second precursor each attaches to a lowermost nanostructure of the upper nanostructures in a cross-sectional view.
